(19) United States
(12) Patent Application Publication
(10) Pub. No.: US 2013/0038641 A1
(43) Pub. Date: Feb. 14, 2013

(54) DISPLAY DEVICE AND METHOD FOR MANUFACTURING THE DISPLAY DEVICE

(71) Applicant: Takahiko MUNEYOSHI, Chiba (JP)

(72) Inventor: Takahiko MUNEYOSHI, Chiba (JP)

(73) Assignee: Japan Display East Inc.

(21) Appl. No.: 13/569,365

(22) Filed: Aug. 8, 2012

(30) Foreign Application Priority Data
Aug. 10, 2011 (JP) 2011-175307

(51) Int. Cl. G09G 5/10; H01L 33/48

(52) U.S. Cl. 345/690; 438/34; 257/E33.056

(57) ABSTRACT

A display device and a method for manufacturing the same which can improve the reliability of TFTs and provide good contrast characteristics are provided. A display device according to the present invention includes a light-transmissive substrate; an impurity-doped layer provided in a part of the light-transmissive substrate; an insulating film provided on the impurity-doped layer and the light-transmissive substrate; a TFT circuit formed on the insulating film and including a plurality of TFTs; and a shutter array including a plurality of shutters drivable by the TFT circuit.

### CROSS-REFERENCE TO RELATED APPLICATIONS

This application is based upon and claims the benefit of priority from the prior Japanese Patent Application No. 2011-175307, filed on 10 Aug. 2011, the entire contents of which are incorporated herein by reference.

### FIELD

The present invention relates to a display device using a mechanical shutter and a method for manufacturing the same.

### BACKGROUND

Recently, a display device using a mechanical shutter to which a MEMS (Micro Electronic Mechanical Systems) technology is applied (hereinafter, such a shutter will be referred to as a “MEMS shutter” or simply a “shutter”) has been a target of attention. A display device using a MEMS shutter (hereinafter, referred to as a “MEMS display device”) opens or closes a MEMS shutter provided in correspondence with each of pixels, at a high speed by use of a TFT, to control the amount of light to be transmitted through the shutter, and thus adjusts the brightness of an image. A mainstream system of such MEMS display devices is a time-ratio gray scale system of displaying an image by sequentially switching light provided from one of LED backlight units of red, green and blue to light provided from another of the LED backlight units. Accordingly, the MEMS display devices have features that polarizing films or color filters used for a liquid crystal display device are not required, and as compared with a liquid crystal display device, the utilization factor of light from the backlight unit is about 10 times higher, the power consumption is no more than half, and the color reproducibility is superior.

A MEMS display device is formed as follows. A TFT including switching elements for driving MEMS shutters, and gate and data drivers for driving the switching elements is formed on a substrate on which an aperture layer is formed. Terminals for supplying signals from an external device to the TFT are also formed on the substrate. On such a substrate having the TFT and the terminals are formed thereon, a passivation film (insulating film) for covering the TFT and the terminals is formed, and MEMS shutters electrically connected to the terminals are formed on the passivation film.

Hereinafter, with reference to FIG. 9 through 11, a structure of a substrate including MEMS shutters will be described. FIG. 9 shows a structure in which a plurality of MEMS shutters 202 are provided respectively on pixels 201 on a substrate 204 including an aperture layer 250. FIG. 10 is an isometric view showing a structure of the substrate 204 shown in FIG. 9. FIG. 11 is a cross-sectional view showing a structure of the substrate 204 shown in FIG. 10.

As shown in FIG. 11, the substrate 204 includes a transparent substrate 206 formed of glass or the like, and the aperture layer 250 for blocking light and light-transmissive regions 254 provided on the transparent substrate 206. The aperture layer 250 is structured to block light from a backlight unit and also suppress output of unnecessary light reflected inside the MEMS display device, in order to prevent decrease of contrast of the MEMS display device. For example, as shown in FIG. 11, the aperture layer 250 includes a high refractive index layer 258, a low refractive index layer 260, a metal reflection layer 262, and a light absorption layer 264 stacked in this order. These layers are covered with a light-transmissive dielectric layer 268. In this structure, parts of the dielectric layer 268 provided on the substrate 206 which do not overlap the aperture layer 250 act as the light-transmissive regions 254. As shown in FIG. 9, on the substrate 204 having such a structure, actuators 203, transistors 210, capacitors 212, gate lines 207, data lines 208 and the like for driving the MEMS shutters 202 are formed in correspondence with the pixels 201. Thus, an active matrix circuit is formed. The MEMS shutters 202 each have a plurality of openings 214, and are structured such that light transmitted through these openings 214 and then through the light-transmissive regions 254 formed in the substrate 204 is visually recognized by the human eye.

In a conventional MEMS display device, the aperture layer 250 is formed of Al, Cr, Au, Ag, Cu, Ni, Ta, Ti, Nd, Nb, W, Mo or the like or an alloy thereof, by vapor deposition and patterning performed on the substrate 206. (see, for example, Japanese Laid-Open Patent Publication No. 2008-533510). The aperture layer 250 may act as a black matrix, which may be formed of MoCr, MoW, MoTi, MoTa, TiW or TiCr, or an alloy thereof, or may have a rough surface of simple metal such as Ni or Cr. Other materials usable for the aperture layer 250 include semiconductor materials such as amorphous or polycrystalline Si, Ge, CdTe, InGaAs and the like, colloid graphite (carbon), alloys such as SiGe and the like, and metal oxides and metal nitrides including CuO, NiO, Cr₂O₃, AgO, SnO, ZnO, TiO, Ta₂O₅, MoO₃, CrN, TiN and TaN.

However, in the case where the aperture layer 250 is formed of a metal film or a metal-rich oxide film as described above, there is a problem that during the formation of the active matrix circuit on the substrate 204, especially while amorphous silicon is changed into polycrystalline silicon (low temperature polycrystalline silicon) by irradiation with laser light, the heat for melting and crystallization easily escapes and thus low temperature polycrystalline silicon having good characteristics is not obtained.

In the case where the aperture layer 250 is formed of a metal oxide film or a metal nitride film on the substrate 206 formed of glass and then the light-transmissive regions 254 are formed by etching, there is a problem that since the etchant has a property of melting the substrate 206, the alkaline metal contained in the substrate 206 may elute and thus decline the performance of the semiconductor layer provided to form TFTs. This makes the process for forming the light-transmissive regions 254 difficult to carry out.

The present invention made in light of the above-described problems provides a display device and a method for manufacturing the same which improve the reliability of TFTs and provide good contrast characteristics, by forming a light attenuation layer (e.g., impurity-doped layer described later) by ion implantation on the substrate on which the TFTs are to be formed.

### SUMMARY

Provided according to an embodiment of the present invention is a display device including a light-transmissive substrate; an impurity-doped layer provided in a part of the light-transmissive substrate; an insulating film provided on the impurity-doped layer and the light-transmissive substrate; a TFT circuit formed on the insulating film and including a plurality of TFTs; and a MEMS shutter array including a plurality of MEMS shutters drivable by the TFT circuit.

Provided according to an embodiment of the present invention is a method for manufacturing a display device including forming an impurity-doped layer in a part of a light-transmissive substrate; forming an insulating film on the impurity-doped layer and the light-transmissive substrate; and forming a TFT circuit including a plurality of TFTs and a plurality of MEMS shutters respectively connected to the plurality of TFTs on the insulating film.

### BRIEF DESCRIPTION OF DRAWINGS

FIG. 1 shows a display device in an embodiment according to the present invention; FIG. 1(a) is an isometric view of the display device, and FIG. 1(b) is a plan view thereof;

FIG. 2 is a circuit block diagram of a display device in an embodiment according to the present invention;

FIG. 3 shows a general structure of a MEMS shutter usable for a display device in an embodiment according to the present invention;

FIG. 4 is a cross-sectional view showing an example of structure of a display device in Embodiment 1 according to the present invention;

FIG. 5 is a cross-sectional view showing steps for manufacturing a display device in an embodiment according to the present invention;

FIG. 6 is a plan view showing an example of structure of a substrate usable for a display device in an embodiment according to the present invention;

FIG. 7 is a cross-sectional view showing an example of structure of a display device in Embodiment 1 according to the present invention;

FIG. 8 is a cross-sectional view showing an example of structure of a display device in Embodiment 2 according to the present invention;

FIG. 9 is an isometric view showing a general structure of a substrate including MEMS shutters usable for a conventional display device;

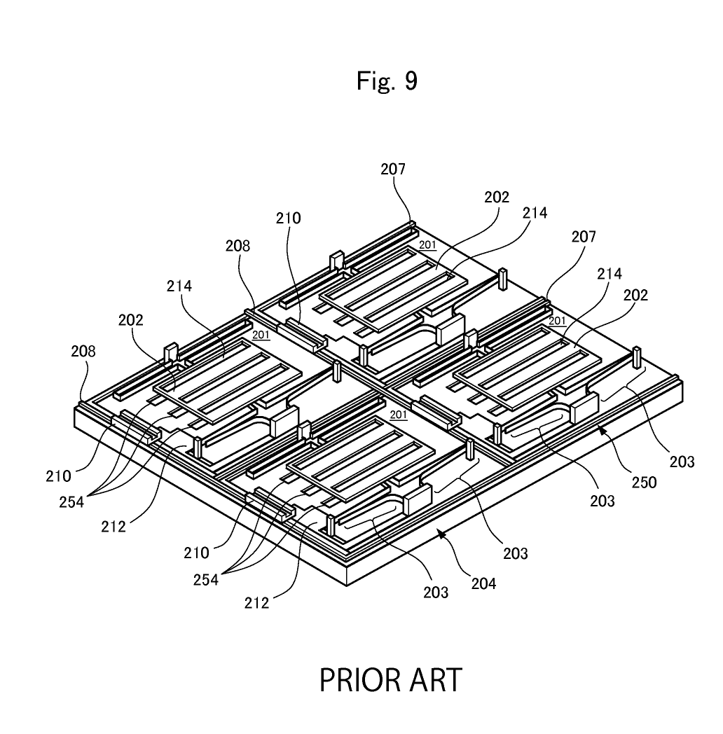

FIG. 10 is an isometric view showing an example of structure of the substrate usable for the conventional display device shown in FIG. 9; and

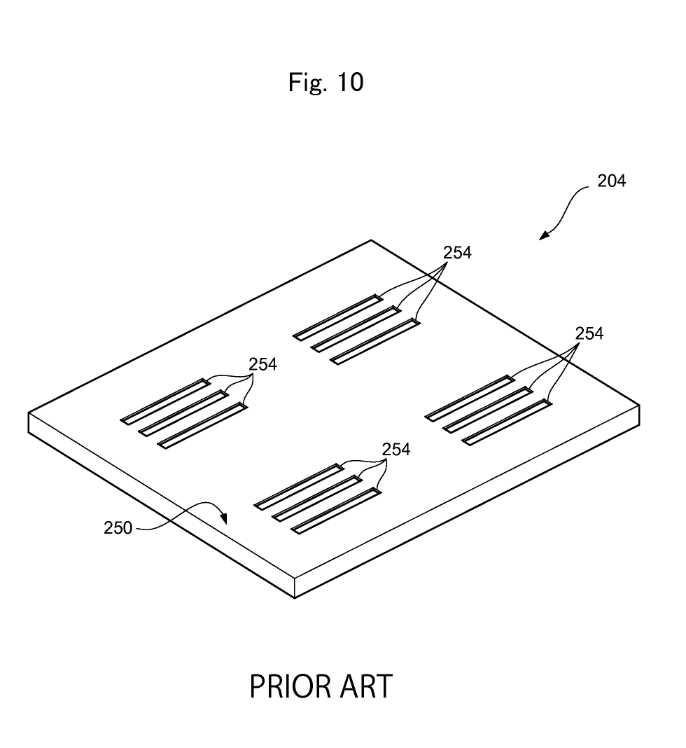

FIG. 11 is a cross-sectional view showing an example of structure of the substrate usable for the conventional display device shown in FIG. 10.

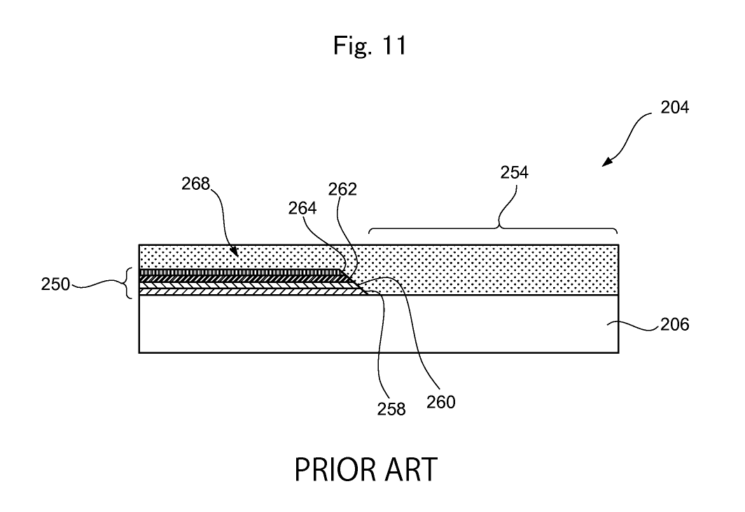

### DESCRIPTION OF EMBODIMENTS

Hereinafter, display devices in embodiments according to the present invention will be described with reference to the drawings. A display device according to the present invention is not limited to those of the following embodiments and may be modified in any of various manners.

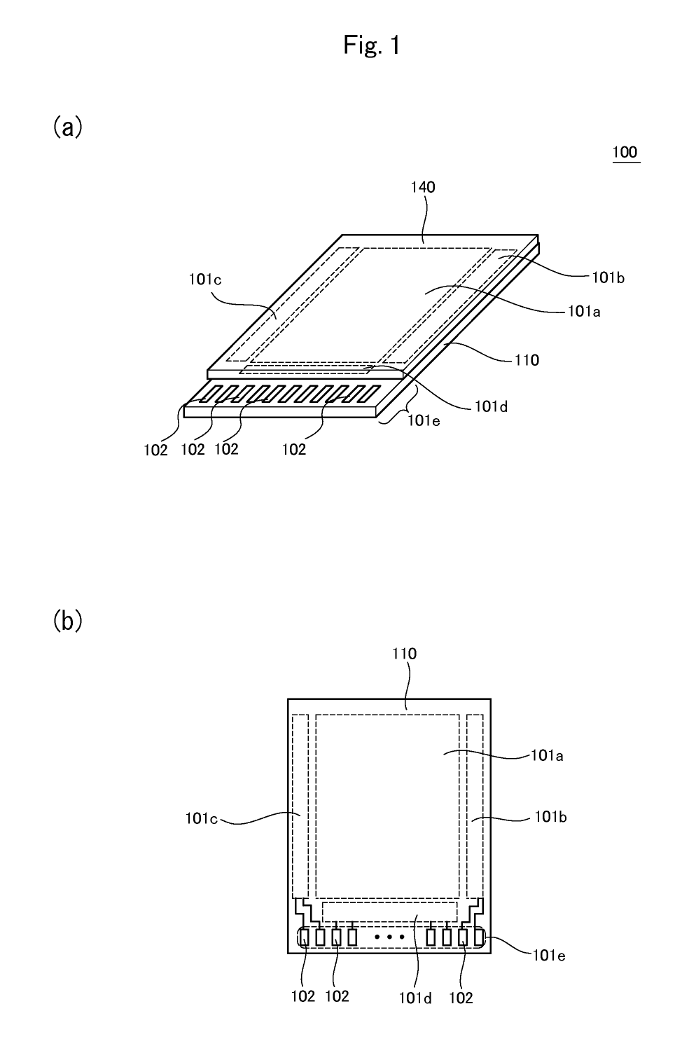

FIGS. 1(a) and (b) show a display device 100 in an embodiment according to the present invention. FIG. 1(a) is an isometric view of the display device 100, and FIG. 1(b) is a plan view thereof. The display device 100 in this embodiment includes a substrate 110 and a counter substrate 140. The substrate 110 includes a display section 101a, driving circuits 101b, 101c and 101d, and a terminal section 101e. The substrate 110 and the counter substrate 140 are joined together by use of a sealing material or the like.

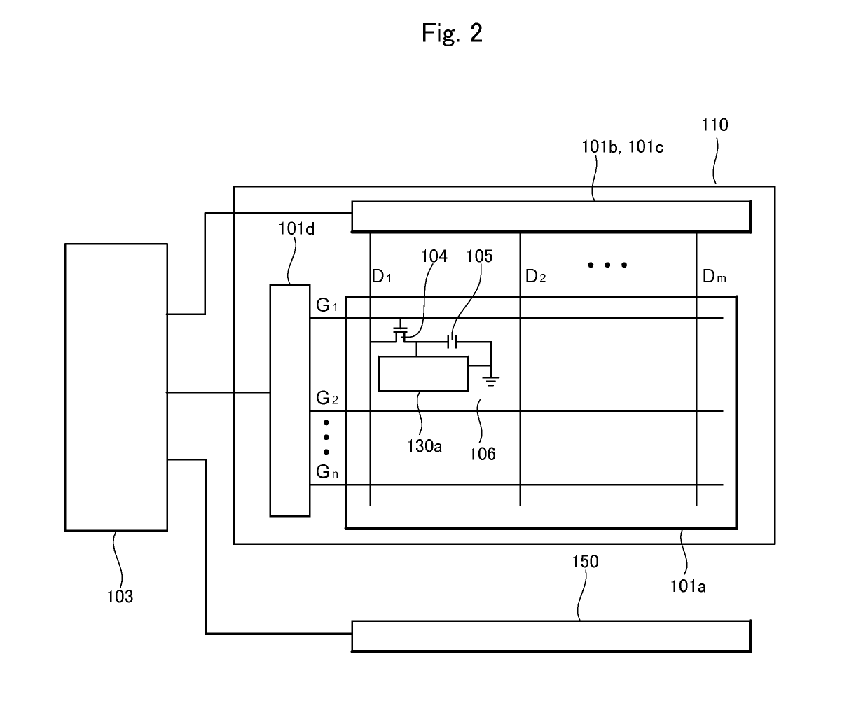

FIG. 2 is a circuit block diagram of the display device 100 in an embodiment according to the present invention. The display device 100 in an embodiment according to the present invention shown in FIG. 2 is supplied with an image signal and a control signal from a controller 103. The display device 100 in an embodiment according to the present invention shown in FIG. 2 is also supplied with light from a backlight unit 150 controlled by the controller 103. The display device 100 may be structured to include the controller 103 and the backlight unit 150.

As shown in FIG. 2, the display section 101a includes pixels 106 arranged in a matrix and respectively provided in correspondence with intersections of gate lines (G1, G2, . . . , Gn) and data lines (D1, D2, . . . , Dm). Each of the pixels 106 includes a MEMS shutter 130a, a switching element (TFT) 104, and a storage capacitance 105. The driving circuits 101b and 101c are data drivers, and supply data signals to the switching elements 104 via the data lines (D1, D2, . . . , Dm). The driving circuit 101d is a gate driver and supplies gate signals to the switching elements 104 via the gate lines (G1, G2, . . . , Gn). In this embodiment, as shown in FIG. 1, the driving circuits 101b and 101c as the data drivers are provided to have the display section 101a therebetween, but the arrangement of the driving circuits 101b and 101c is not limited to this. Each switching element 104 drives the corresponding MEMS shutter 130a based on the data signal supplied from the corresponding data line among the data lines (D1, D2, . . . , Dm).

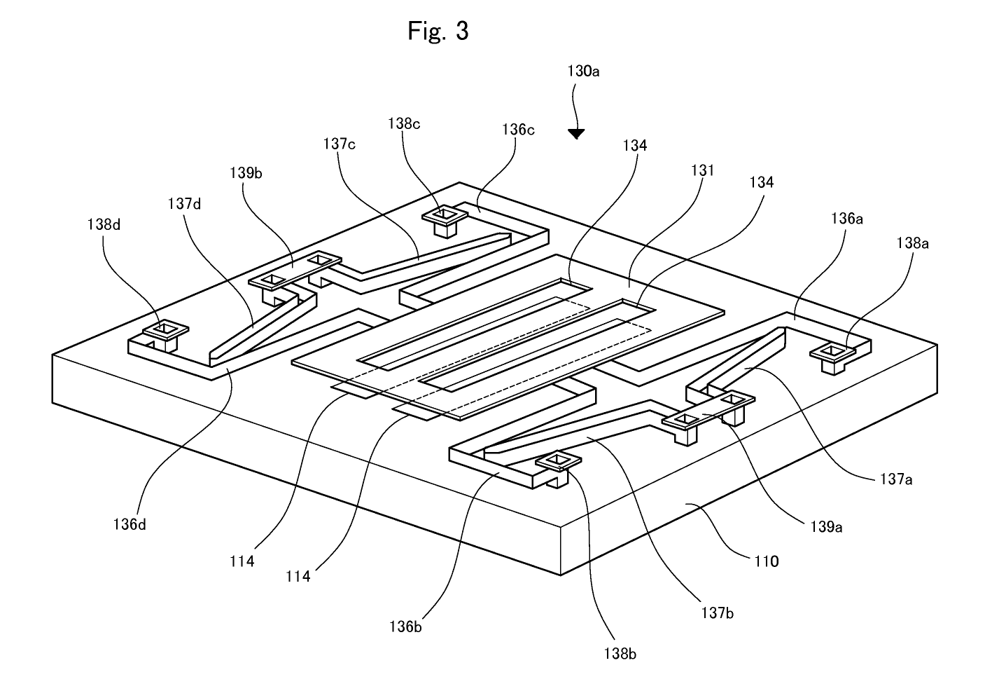

Now, with reference to FIG. 3, a structure of the MEMS shutter 130a will be described. FIG. 3 shows a structure of the MEMS shutter 130a usable for the display device 100 in an embodiment according to the present invention. FIG. 3 shows one MEMS shutter 130a for the convenience of description, but the display device 100 in an embodiment according to the present invention includes a plurality of MEMS shutters 130a shown in FIG. 3 arranged in a matrix on the substrate 110.

The MEMS shutter 130a includes a shutter 131, first springs 136a, 136b, 136c and 136d, second springs 137a, 137b, 137c and 137d, and anchor sections 138a, 138b, 138c, 138d, 139a and 139b. The shutter 131 has openings 134, and a main body of the shutter 131 acts as a light blocking section. The substrate 110 also has a plurality of light-transmissive regions 114. The counter substrate 140 shown in FIG. 1 has openings (not shown in FIG. 1) for transmitting light. The counter substrate 140 is joined to the substrate 110 via a sealing material or the like such that the openings of the counter substrate 140 and the light-transmissive regions 114 of the substrate 110 generally overlap each other in a planar direction. The display device 100 is structured such that light supplied from behind the counter substrate 140 and transmitted through the openings of the counter substrate 140 is transmitted through the openings 134 of the shutter 131 and then through the light-transmissive regions 114 of the substrate 110 and thus is visually recognized by the human eye. The MEMS shutter 130a in this embodiment is merely an example of MEMS shutter usable for the display device 100 according to the present invention. The MEMS shutter usable for a display device according to the present invention is not limited to having the structure shown in FIG. 3, but may be any MEMS shutter which can be driven by a switching element.

One side of the shutter 131 is connected to the anchor sections 138a and 138b via the first springs 136a and 136b. The anchor sections 138a and 138b have a function of supporting the shutter 131 such that shutter 131 floats above a surface of the substrate 110 together with the first springs 136a and 136b. The anchor section 138a is electrically connected to the first spring 136a, and the anchor section 138b is electrically connected to the first spring 136b. The anchor section 138a and 138b are each supplied with a bias potential from the switching element 104, and thus the first springs 136a and 136b are each supplied with the bias potential. The second springs 137a and 137b are electrically connected to the anchor section 139a. The anchor section 139a has a function of supporting the second springs 137a and 137b such that the second springs 137a and 137b float above the surface of the substrate 110. The anchor section 139a is supplied with a ground potential, and thus the second springs 137a and 137b are each supplied with the ground potential. The anchor section 139a may be supplied with a predetermined potential instead of the ground potential. This is also applicable to the following description regarding the ground potential.

The other side of the shutter 131 is connected to the anchor sections 138c and 138d via the first springs 136c and 136d. The anchor sections 138c and 138d have a function of supporting the shutter 131 such that shutter 131 floats above the surface of the Substrate 110 together with the first springs 136c and 136d. The anchor section 138c is electrically connected to the first spring 136c, and the anchor section 138d is electrically connected to the first spring 136d. The anchor section 138c and 183d are each supplied with a bias potential from the switching element 104, and thus the first springs 136c and 136d are each supplied with the bias potential. The second springs 137c and 137d are electrically connected to the anchor section 139b. The anchor section 139b has a function of supporting the second springs 137c and 137d such that the second springs 137c and 137d float above the surface of the substrate 110. The anchor section 139b is supplied with a ground potential, and thus the second springs 137c and 137d are each supplied with the ground potential.

As described above, in this embodiment, the anchor sections 138a and 138b are each supplied with a bias potential from the switching element 104, and thus the first springs 136a and 136b are each supplied with the bias potential. Also, the anchor section 139a is supplied with a ground potential, and thus the second springs 137a and 137b are each supplied with the ground potential. By a potential difference of the first springs 136a and 136b from the second springs 137a and 137b, the first spring 136a and the second spring 137a are electrostatically driven and moved to be attracted to each other, and the first spring 136b and the second spring 137b are electrostatically driven and moved to be attracted to each other. Thus, the shutter 131 is moved.

Similarly, the anchor sections 138c and 138d are each supplied with a bias potential from the switching element 104, and thus the first springs 136c and 136d are each supplied with the bias potential. Also, the anchor section 139b is supplied with a ground potential, and thus the second springs 137c and 137d are each supplied with the ground potential. By a potential difference of the first springs 136c and 136d from the second springs 137c and 137d, the first spring 136c and the second spring 137c are electrostatically driven and moved to be attracted to each other, and the first spring 136d and the second spring 137d are electrostatically driven and moved to be attracted to each other. Thus, the shutter 131 is moved.

Such driving on the shutter 131 by an electrostatic force allows the shutter 131 to operate at high speed. Accordingly, the display device 100 can provide gray scale display by changing the position of the shutter 131 by high speed driving and thus controlling the amount of light transmitted through the openings 134. The display device 100 can also provide color display by performing sequential driving (field sequential driving) on the light of the three colors of R, G and B emitted by the backlight unit 150. In this case, the polarizing plates and the color filters, which are required in a liquid crystal display device, are not necessary. Thus, the light from the backlight unit 150 can be used without being attenuated.

In this embodiment, the first springs, the second springs and the anchor sections are provided on both sides of the shutter 131, but the display device 100 according to the present invention is not limited to such a structure. For example, the first springs, the second springs and the anchor sections may be provided on one side of the shutter 131, and only the first springs and the anchor sections may be provided on the other side of the shutter 131. The first springs and the anchor sections provided on the other side of the shutter 131 may have a function of supporting the shutter 131 such that the shutter 131 floats above the substrate 110, and the first springs and the second springs on the one side of the shutter 131 may be electrostatically driven to move the shutter 131.

### Embodiment 1

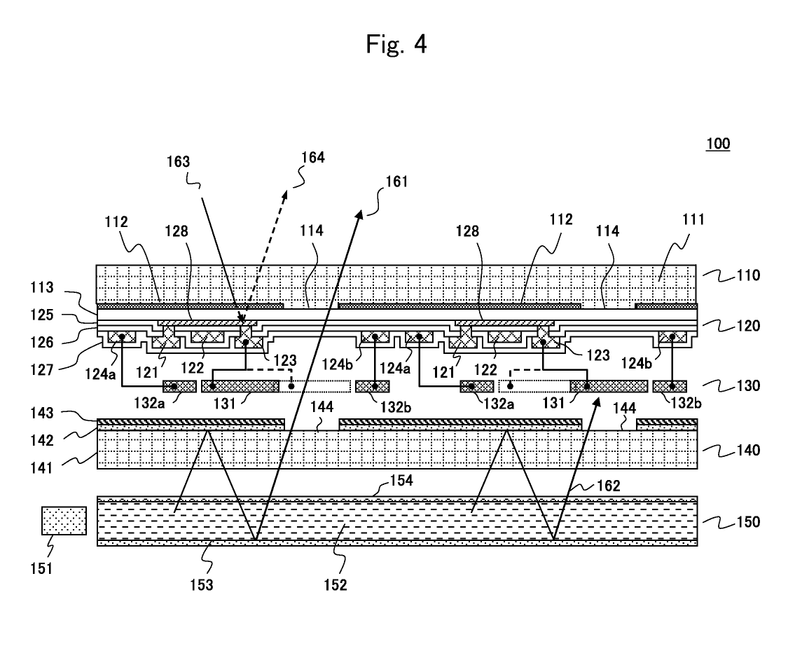

Hereinafter, with reference to FIG. 4 through FIG. 7, a structure of, and a method for producing, the display device 100 in Embodiment 1 according to the present invention will be described.

FIG. 4 is a cross-sectional view showing a structure of the display device 100 in Embodiment 1 according to the present invention. The display device 100 includes the substrate 110 including a light attenuation layer 112 (impurity-doped layer), a TFT circuit layer 120, a MEMS shutter array 130, the counter substrate 140, and the backlight unit 150.

As shown in FIG. 4, the substrate 110 is provided on the side of a front surface of the TFT circuit layer 120, the MEMS shutter array 130, the counter substrate 140, and the backlight unit 150. The display device 100 is structured such that the substrate 110 is provided on the side of a display screen. The substrate 110 includes the light attenuation layer 112 provided on a surface of a glass substrate 111 and the light-transmissive regions 114, which are parts of the glass substrate 111 where the light attenuation layer 112 is not provided. On a surface of the substrate 110 including the light attenuation layer 112, a protective film 113 which is insulating and light-transmissive is provided, so that impurities are not mixed into the TFT circuit layer 120 provided on the protective film 113.

On the substrate 110, the TFT circuit layer 120 is provided. The TFT circuit layer 120 includes a plurality of TFTs provided respectively in correspondence with for the plurality of MEMS shutters 130a (see FIG. 3). The plurality of TFTs each include a semiconductor layer 128, a source electrode 121, a gate electrode 122, a drain electrode 123, and control electrode lines 124a and 124b. Between the semiconductor layer 128 and the gate electrode 122, a gate insulating film 125 is provided. The control electrode lines 124a and 124b are insulated from other lines and electrodes by an interlayer insulating layer 126. On a surface of the TFT circuit layer 120, a protective layer 127 is provided for insulating the TFT circuit layer 120 from the surrounding elements. The gate insulating film 126, the interlayer insulating layer 126 and the protective film 127 are formed of a material which is insulating and light-transmissive.

On the TFT circuit layer 120 provided on the substrate 110, the MEMS shutter array 130 is provided. The MEMS shutter array 130 includes a plurality of the shutters 131 provided in a matrix and a plurality of control electrodes 132a and 132b. The control electrodes 132a and 132b shown in FIG. 4 correspond to the second springs 137a, 137b, 137c and 137d shown in FIG. 3. As shown in FIG. 4, the plurality of shutters 131 and the plurality of control electrodes 132a and 132b are formed to float above the surface of the substrate 110. The plurality of shutters 131 and plurality of control electrodes 132a and 132b are each supplied with a potential from the control electrode lines 124a and 124b of the corresponding TFT, and the shutter 131 is driven by the potential difference. As described above, the shutter 131 has a plurality of openings 134 (see FIG. 3). The shutter 131 is driven at high speed to have the position thereof changed, so that the amount of light transmitted through the openings 134 is controlled.

As shown in FIG. 4, the counter substrate 140 has a structure in which a reflective film 142 and a light absorption film 143 are sequentially stacked on a glass substrate 141. The counter substrate 140 has a plurality of openings 144, which are formed by etching away parts of the reflective film 142 and the light absorption film 143. As described above, the counter substrate 140 and the substrate 110 are joined together by use of a sealing material or the like. In the step of joining, the openings 144 formed in the glass substrate 141 are located to generally overlap the light-transmissive regions 114 formed in the substrate 110 in a planar direction. Thus, light from the backlight unit 150 located rear to the counter substrate 140 is transmitted. After the substrate 110 and the counter substrate 140 are joined together by a sealing material, a damping material such as silicone oil or the like may be enclosed in a space between the substrate 110 and the counter substrate 140. The viscosity of the damping material and the conditions for enclosing the damping material may be selected so that the operation of the shutters 131 is not hindered and the shutters 131 are not, for example, corroded.

The backlight unit 150 includes a light source 151, a lightguide plate 152, a reflective film 153, and a diffusing plate 154. As shown in FIG. 4, the light source 151 is located adjacent to a side surface of the lightguide plate 152. Light emitted by the light source 151 is reflected and scattered inside the lightguide plate 152, and then is emitted toward the counter substrate 140. In order to effectively utilize the light from the light source 151, the diffusing plate 154 is provided on a surface of the lightguide plate 152, and a reflective film 153 is provided on a bottom surface of the lightguide plate 152. As the light source 151, red, green and blue LEDs may be used and may be driven sequentially. The backlight unit 150 is not limited to be of an edge-lit type shown in FIG. 4 and may be in any of various forms in accordance with the specifications of the display device.

The light emitted by the light source 151 is directed toward the counter substrate 140 via the lightguide plate 152 and the diffusing plate 154. The light reflected by the reflective film 142 of the counter substrate 140 returns back to the backlight unit 150 and is reflected by the reflective film 153 provided on the lightguide plate 152 to be reused. In an open state where the shutter 131 transmits the light from the backlight unit 150, light 161 transmitted through the openings 144 and the light-transmissive regions 114 is recognized as a bright pixel by the human eye. By contrast, in a closed state of the shutter 131, light 162 transmitted through the openings 144 is blocked by the shutter 131 and thus is recognized as a dark pixel by the human eye. In this manner, an open state and a closed state of the shutter 131 are switched to each other at high speed to control the amount of light directed toward the display screen. Thus, the light can be recognized as an image by the human eye.

As shown in FIG. 4, incident light 163 incident from outside is reflected inside the display device 100 and becomes reflected light 164. More specifically, when the incident light 163 is incident on the light attenuation layer 112 of the substrate 110, the incident light 163 is attenuated by the light attenuation layer 112. Therefore, the reflected light 164 is sufficiently weaker than the incident light 163. For this reason, the light 161 from the light source 151 can have good contrast with respect to the reflected light 164 with certainty. If the substrate 110 does not include the light attenuation layer 112, the incident light 163 is reflected by the semiconductor layer 128 and the control electrode lines 124a and 124b and thus becomes strong reflected light. As a result, the contrast is decreased and the display is difficult to view. Preferably, the transmittance of the light attenuation layer 112 is 70% or less. In this case, the intensity of the reflected light 164 can be about 50% or less of the incident light 163. More preferably, the transmittance of the light attenuation layer 112 is 30% or less. In this case, the intensity of the reflected light 164 can be about 10% or less of the incident light 163.

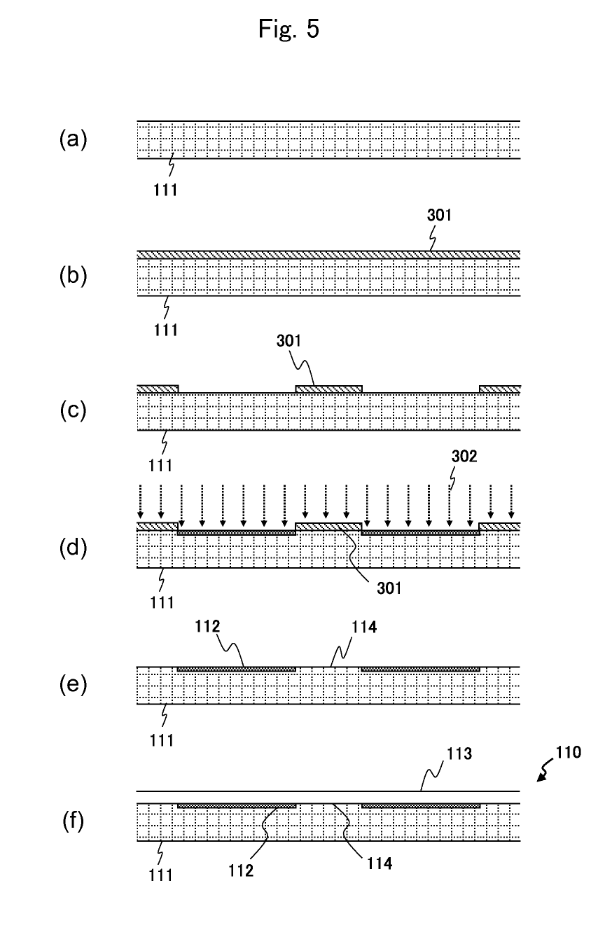

A method for manufacturing the substrate 110 including the light attenuation layer 112 will be described with reference to FIG. 5. FIG. 5 provides cross-sectional views showing steps for manufacturing the substrate 110 usable in the display device 100 in one embodiment according to the present invention.

First, as shown in FIG. 5(a), the glass substrate 111 is prepared. The glass substrate 111 has a thickness of 0.2 mm to 0.5 mm and is transparent or light-transmissive. For example, the glass substrate 111 is formed of quartz glass, high-silica glass, soda lime glass or the like.

Next, as shown in FIG. 5(b), a resist layer 301 is formed on the glass substrate 111. As shown in FIG. 5(c), the resist layer 301 is patterned by photolithography. The resist layer 301 is patterned such that only parts which are to correspond to the light-transmissive regions 114 are left and parts which are to correspond to the light attenuation layer 112 are removed.

Next, as shown in FIG. 5(d), ions 302 are implanted into the glass substrate 111 by ion implantation in order to form the light attenuation layer 122. Elements usable as the source of the ions 302 include Cu, Mn, Cr, Fe, V, C, Al, Ti, Nb and the like, and alloys and oxides thereof. The acceleration voltage is 10 keV to 200 keV, and the dose of the ions is 10¹⁴ cm⁻² to 10¹⁷ cm⁻². Such ion implantation allows impurity elements to be buried in an area of a depth of 10 nm to 800 nm from a surface of the glass substrate 111.

Next, the resist layer 301 is removed. As a result, as shown in FIG. 5(e), the parts of the glass substrate 111 into which the ions were implanted become the light attenuation layer 112, and the parts of the glass substrate 111 into which the ions were not implanted by means of the resist layer 301 become the light-transmissive regions 114. Unlike the conventional method of using etching to form the light-transmissive regions 114, this method does not cause components of alkaline metal or the like contained in the glass substrate 111 to be eluted by the etchant. Therefore, the light-transmissive regions 114 can be formed more easily.

Next, as shown in FIG. 5(f), the protective film 113 is formed on the surface of the glass substrate 111 including the light attenuation layer 112. The protective film 113 is formed of SiO₂, SiN or the like which is insulating and light-transmissive. The formation of the protective film 113 prevents the ions 302, buried in the glass substrate 111 for forming the light attenuation layer 112, from being mixed into the TFT circuit layer 120. Thus, the TFT characteristics can be kept good.

By the above-described process, the substrate 110 including the light attenuation layer 112 and the light-transmissive layer 114 in Embodiment 1 according to the present invention is formed. The light attenuation layer 112 formed in the substrate 110 has a transmittance of 70% or less, and therefore the intensity of the reflected light 164 can be about 49% (0.7×0.7=0.49) or less of the intensity of the incident light 163. Owing to this, the display device 100 having good contrast characteristics can be provided.

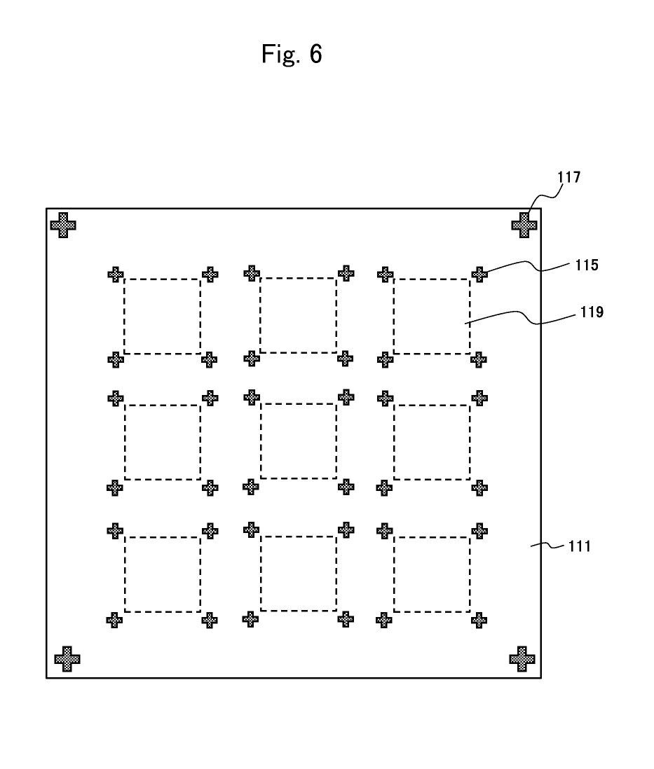

Referring to FIG. 6, during the step of forming the light attenuation layer 112 described above with reference to FIG. 5, a plurality of position alignment marks 115 and 117 may be formed on the glass substrate 111 at the same time as the formation of the light attenuation layer 112. The position alignment marks 115 and 117 shown in FIG. 6 are used for position alignment of a photomask which is used for photolithography for forming the TFT circuit layer 120. In FIG. 6, dashed squares 119 each represent a position at which the substrate 110 is to be formed. The display device 100 may be manufactured as follows. At each position 119 at which the substrate 110 is to be formed, the TFT circuit layer 120 and the MEMS shutter array 130 are formed. After the counter substrate 140 is joined to the substrate having the light attenuation layer 120 and the MEMS shutter array 130 provided thereon, the assembly of the substrates is divided by cutting. Thus, a plurality of display devices 100 are manufactured.

As described above, at the same time as the formation of the light attenuation layer 112, the position alignment marks 115 and 117 to be used for the process of forming the TFT circuit layer 120 are formed in advance on the glass substrate 111 by use of the same material as that of the light attenuation layer 112. Owing to this, the light attenuation layer 112 and the light-transmissive regions 114 can be aligned with the TFT circuit layer 120 with high precision in a simple manner. Accordingly, the display device 100 can be provided with improved precision with an improved yield.

After the substrate 110 is formed, the TFT circuit layer 120 is formed by a generally used process, as described below specifically. As the semiconductor layer 128 of the TFT circuit layer 120, an amorphous silicon film is formed on the protective film 113 provided on the substrate 110. Then, the amorphous silicon is changed into low temperature polycrystalline silicon by laser annealing. During this step, the thermal conductivity of the light attenuation layer 112 formed on the glass substrate 111 can be approximately the same as the thermal conductivity of the glass substrate 111 owing to the above-described method of forming the light attenuation layer 112. Therefore, as compared with the case where the light attenuation layer 112 is formed of a metal film or a metal-rich film, heat is not escaped while the amorphous silicon is melted and crystallized to form a polycrystalline silicon film. For this reason, a low temperature polycrystalline silicon film having good characteristics can be provided. Accordingly, the display device including the TFT circuit layer 120 operating stably can be provided.

As described above, according to the display device 100 and a method for manufacturing the same in Embodiment 1 of the present invention, the light attenuation layer 112 is formed on the surface of the glass substrate 111 by ion implantation. Owing to this, the reliability of the TFT circuit layer 120 formed on the substrate 110 in a later step can be improved. Therefore, the display device 100 operating highly precisely and stably can be provided. In addition, the light attenuation layer 112 formed in the substrate 110 can attenuate the intensity of the incident light 163 incident from outside and thus weaken the intensity of the reflected light 164 to 50% or less of that of the incident light 163. Therefore, the display device 100 having good contrast characteristics can be provided.

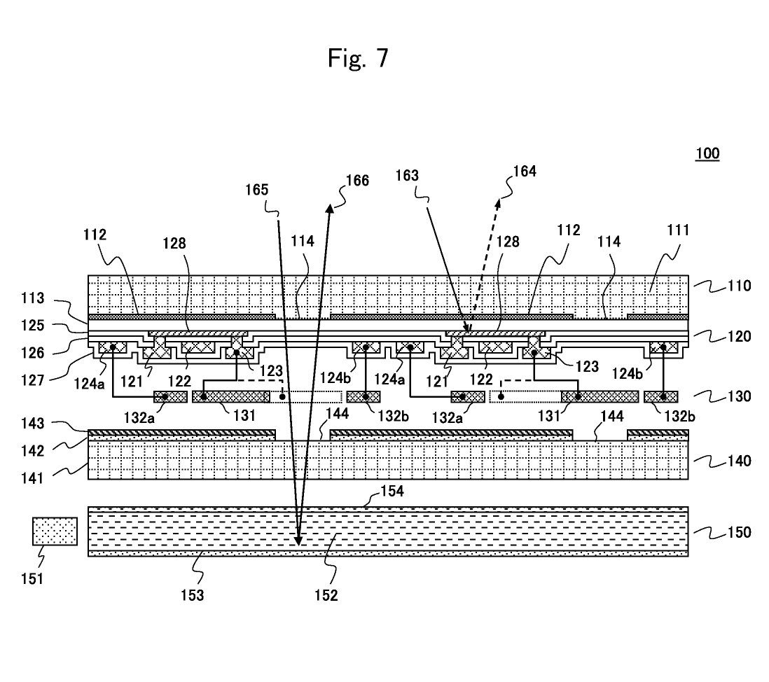

As shown in FIG. 7, the display device 100 can maintain the good contrast characteristics even in a reflection display mode, in which the light source 151 is off. When the shutter 131 is in an open state, external light 165 incident from outside is transmitted through the light-transmissive regions 114 and the openings 144 and is reflected by the reflective film 153 to become light 166. The light 166 enters the human eye and thus is recognized as a bright pixel by the human eye. The incident light 163 incident on the display device 100 from outside is reflected to become the reflected light 164. The reflected light 164 is sufficiently weaker than the incident light 163 as a result of being attenuated by the light attenuation layer 112. Therefore, as in the display device 100 shown in FIG. 4, the light 166 can maintain good contrast with respect to the reflected light 164. Thus, the display device 100 having good contrast characteristics can be provided.

### Embodiment 2

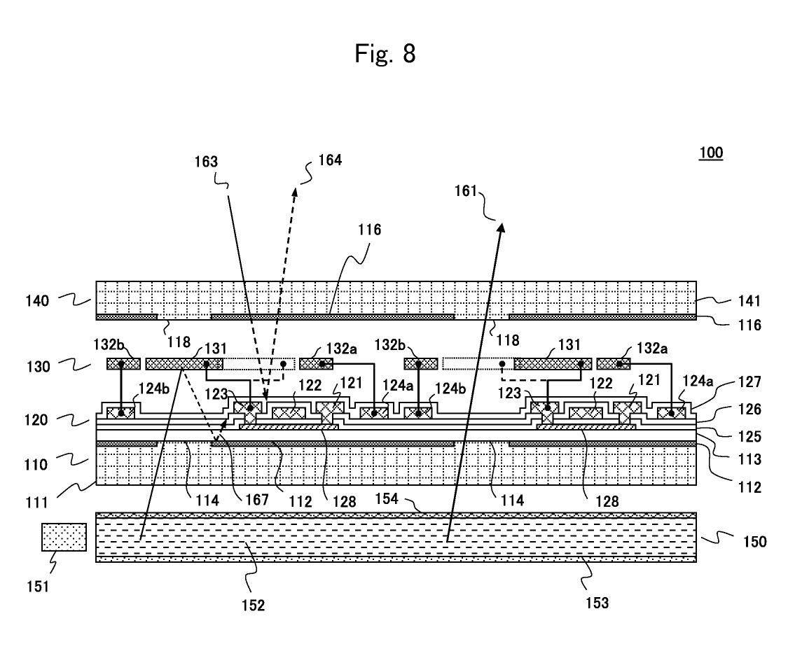

Hereinafter, with reference to FIG. 8, a structure of, and a method for producing, a display device 100 in Embodiment 2 according to the present invention will be described.

FIG. 8 is a cross-sectional view showing a structure of the display device 100 in Embodiment 2 according to the present invention. The display device 100 includes the substrate 110 including the light attenuation layer 112, the TFT circuit layer 120, the MEMS shutter array 130, the counter substrate 140, and the backlight unit 150.

In the display device 100 in Embodiment 2, the substrate 110, the TFT circuit layer 120, the MEMS shutter array 130 and the backlight unit 150 have the same structure as in the display device 100 in Embodiment 1. In the following, elements having substantially the same structure as that of the corresponding elements of the display device 100 in Embodiment 1 will not be described in detail.

Unlike in the display device 100 in Embodiment 1, in the display device 100 in Embodiment 2, the backlight unit 150 is located rear to the substrate 110 instead of the counter substrate 140. The light 161 from the backlight unit 150 is transmitted through the openings 114 of the substrate 110 and the openings 134 of the shutter 131, then is transmitted through light-transmissive regions 118 formed in the counter substrate 140, and thus is recognized as an image. Accordingly, as shown in FIG. 8, in this embodiment, the display device 100 is structured such that the counter substrate 140 is on the side of the display screen.

As shown in FIG. 8, the counter substrate 140 has a structure in which a light attenuation layer 116 and the light-transmissive regions 118 are provided on the glass substrate 141. In this embodiment, the counter substrate 140 is formed of substantially the same material as that of, by substantially the same method as that of, the substrate 110 of the display device 100 in Embodiment 1. Therefore, the counter substrate 140 has substantially the same structure as that of the glass substrate 111 including the light attenuation layer 112 and the light-transmissive layers 114 as shown in FIG. 5(e). Accordingly, as shown in FIG. 8, the incident light 163 incident from outside is reflected inside the display device 100 to become the reflected light 164, which is sufficiently weaker than the incident light 163 as a result of being attenuated by the light attenuation layer 116. Owing to this, in Embodiment 2 also, the display device 100 having good contrast characteristics can be provided as in Embodiment 1.

In the display device 100 in Embodiment 2, when the shutter 131 is in a closed state, light from the backlight unit 150 is blocked by the shutter 131 and is diffuse-reflected between the TFT circuit layer 120 and the MEMS shutter array 130, which may cause scattered light 167 to be incident on the TFT circuit layer 120. However, the intensity of the scattered light 167 can be decreased by the light attenuation layer 112 included in the substrate 110, and therefore highly strong light can be prevented from being incident directly on the TFT circuit layer 120. Owing to this, malfunction of the TFT circuit layer 120 can be prevented.

In the display device 100 in Embodiment 2 also, the light attenuation layer 112 included in the substrate 110 is formed of substantially the same material as that of, by substantially the same method as that of, the light attenuation layer 112 of the display device 100 in Embodiment 1. Therefore, during the step of forming the semiconductor layer 128 of the TFT circuit layer 120, low temperature polycrystalline silicon having good characteristics can be formed. Thus, the reliability of the TFT circuit layer 120 can be improved. In the display device 100 in Embodiment 2, instead of the light attenuation layer 116 included in the counter substrate 140, a light absorption layer of a black resin film or a metal film such as Cr or the like may be, provided. In this case also, the incident light 163 can be prevented from becoming reflected light, and thus the display device 100 having good contrast characteristics can be provided.

As described above, in Embodiment 2, the display device 100 having good contrast characteristics and operating highly precisely and stably can be provided, like the display device 100 in Embodiment 1.

As described above, the present invention provides the display device 100 and a method for manufacturing the same which improve the reliability of the TFTs and provide good contrast characteristics, by forming the light attenuation layer 112 by ion implantation on the substrate 110 on which the TFTs are to be formed.

What is claimed is:

1. A display device, comprising:
a light-transmissive substrate;
an impurity-doped layer provided in a part of the light-transmissive substrate;
an insulating film provided on the impurity-doped layer and the light-transmissive substrate;
a TFT circuit formed on the insulating film and including a plurality of TFTs; and
a shutter array including a plurality of shutters drivable by the TFT circuit.

2. A display device according to claim 1, wherein the impurity-doped layer contains an element among Cu, Mn, Cr, Fe, V, C, Al, Ti and Nb.

3. A display device according to claim 1, wherein the impurity-doped layer is provided in an area of a depth of 10 nm to 800 nm from a surface of the substrate.

4. A display device according to claim 1, wherein the impurity-doped layer has a light transmittance of 70% or less.

5. A display device according to claim 1, wherein the impurity-doped layer is provided by ion implantation.

6. A display device according to claim 1, further comprising:
a counter substrate which is joined with the light-transmissive substrate and has a plurality of openings; and
a backlight unit provided rear to the light-transmissive substrate and the counter substrate;
wherein light supplied from the backlight unit is transmitted through a part at which the openings of the counter substrate overlap parts of the light-transmissive substrate where the impurity-doped layer is not provided.

7. A method for manufacturing a display device, comprising:
forming an impurity-doped layer in a part of a light-transmissive substrate;
forming an insulating film on the impurity-doped layer and the light-transmissive substrate; and
forming a TFT circuit including a plurality of TFTs and a plurality of shutters respectively connected to the plurality of TFTs on the insulating film.

8. A method for manufacturing a display device according to claim 7, wherein the impurity-doped layer is formed by ion implantation by use of an ion source containing an element among Cu, Mn, Cr, Fe, V, C, Al Ti and Nb.

9. A method for manufacturing a display device according to claim 8, wherein the impurity-doped layer is formed by ion implantation at an acceleration voltage is 10 keV to 200 keV and an ion dose of 10¹⁴ cm⁻² to 10¹⁷ cm⁻².

10. A method for manufacturing a display device according to claim 7, wherein an amorphous silicon film is formed on the insulating film; a polycrystalline silicon film is formed by irradiating the amorphous silicon film with laser; and the TFT circuit is formed by use of the polycrystalline silicon film.
